(19) United States
(12) Patent Application Publication
(10) Pub. No.: US 2009/0191332 A1
(43) Pub. Date: Jul. 30, 2009

(54) Method for manufacturing magnetic recording medium and connecting device used in manufacturing magnetic recording medium

(75) Inventor: Shigeaki Takaya, Nagano (JP)

Correspondence Address: KANESAKA BERNER AND PARTNERS LLP, 1700 DIAGONAL RD, SUITE 310, ALEXANDRIA, VA, 22314-2848, US

(73) Assignee: FUJI ELECTIRC DEVICE TECHNOLOGY CO., LTD., Tokyo (JP)

(21) Appl. No.: 12/320,086

(22) Filed: Jan. 16, 2009

(30) Foreign Application Priority Data
Jan. 29, 2008 (JP) 2008-017476

(51) Int. Cl. B05D 5/12; H01L 21/677

(52) U.S. Cl. 427/131; 414/217

(57) ABSTRACT

In a method for manufacturing a magnetic recording medium, a plurality of vacuum film-formation devices formed separately and operated independently is prepared. The plurality of vacuum film-formation devices is connected by a connecting device provided with a disk transport system.

### BACKGROUND OF THE INVENTION AND RELATED ART STATEMENT

The present invention relates to a method and a device for manufacturing a magnetic recording medium. More particularly, the present invention relates to a method and a device for manufacturing a disk-like magnetic recording medium using a plurality of vacuum film-formation devices.

Disk-like magnetic recording media (including magneto-optical recording media) such as hard disks and MOs (magnet optical disks) have a structure in which multiple thin films comprising a metal or the like are layered on a disk-like substrate. To manufacture these thin films, a dry process is ordinarily employed wherein the thin films are formed using a vacuum chamber. Widely used processes for forming the thin films on disk-like magnetic recording media include, for instance, sputtering film formation and CVD film formation.

Ordinarily, one kind of thin film is formed in one given vacuum chamber, and hence multiple vacuum chambers are required for forming a multilayer film. As a result, the above-described vacuum film-formation devices for manufacturing a magnetic recording medium comprise multiple vacuum chambers, with means for transporting disks between the individual vacuum chambers. For instance, Japanese Patent No. 2699045 (corresponding to U.S. Pat. No. 5,215,420) discloses one such vacuum film-formation device, which is commercially available as MPD-250B from Intevac, Inc. Other such vacuum deposition devices for magnetic recording media include, for instance, C-3040 by Canon Anelva Corp.

In recent years, layer structures in magnetic recording media are incorporating more types of materials, with greater layer counts, as the density of magnetic recording media grows ever higher. In the transition from longitudinal magnetic recording to perpendicular magnetic recording in hard disks, in particular, magnetic recording media for longitudinal magnetic recording can be manufactured by a vacuum film-formation device having about twelve chambers, such as MPD-250B by Intevac, but no fewer than twelve chambers are required in magnetic recording media for perpendicular magnetic recording, where layer counts are higher.

As a result, recent vacuum film-formation devices can manage 20 or more chambers, by providing additional process stations, as disclosed in Japanese Publication of PTC Application No. 2006-517324 (corresponding to U.S. Pat. No. 6,183,831 B1). Such a device is commercially available as 200 Lean, by Intevac.

For manufacturers of magnetic recording media, however, the switching from a currently-owned MPD-250B in normal operation to 200 Lean includes the cost for new equipment, with all the trouble and higher costs involved thereto. If it were possible to manufacture magnetic recording media having higher number of layers for perpendicular magnetic recording, using a currently-owned vacuum film-formation device, the equipment change, which includes changes in operation procedures, is unnecessary, and costs could be kept low.

In the light of the above, the present invention provides a method for manufacturing a magnetic recording medium that allows manufacturing a magnetic recording medium having a greater number of layers, which is difficult to accomplish with a single vacuum film-formation device having an insufficient number of chambers, by connecting vacuum film-formation devices.

The present invention also provides a connecting device for connecting the vacuum film-formation devices.

Further objects and advantages of the invention will be apparent from the following description of the invention.

### SUMMARY OF THE INVENTION

To achieve the above objects, a method for manufacturing a magnetic recording medium of the present invention manufactures a disk-like magnetic recording medium, and comprises the step of using a film-formation apparatus comprising a plurality of vacuum film-formation devices that are connected by way of a connecting device provided with a disk transport system.

Preferably, the connecting device is provided with a disk transport system in a vacuum state. A vacuum state herein means “a specific state in a space that is filled with gas at a pressure lower than an atmospheric pressure”.

Preferably, transport time between the connected vacuum film-formation devices is no greater than 60 seconds, more preferably no greater than 30 seconds.

The connecting device of the present invention connects vacuum film-formation devices used for manufacturing a disk-like magnetic recording medium, the connecting device comprising a disk transport system.

Preferably, the connecting device further comprises a system for generating a vacuum state.

Preferably, moreover, the disk transport system transports a disk through rotation of an arm holding a disk at the tip thereof.

Preferably, the disk is held substantially vertically at the tip of the arm, and the orientation of a disk surface is maintained during transport through rotation of the arm.

The connecting device further comprises, preferably, a system that enables transport by a disk storing package.

The invention allows thus manufacturing a multilayer perpendicular magnetic recording medium, without introducing new devices, by using the connecting device of the present invention for connecting two or more vacuum film-formation devices, even vacuum film-formation devices in which manufacturing of magnetic recording media having a greater number of layers is difficult to accomplish with a single vacuum film-formation device having an insufficient number of chambers. The invention allows thus the costs down while avoiding, for instance, updating of operational procedures and the like that accompany the new equipment.

### BRIEF DESCRIPTION OF THE DRAWINGS

FIG. 1 is a schematic diagram illustrating an embodiment of a conventional method for manufacturing a magnetic recording medium, as viewed from above.

FIG. 2 is a schematic diagram illustrating an embodiment of a method for manufacturing a magnetic recording medium of the present invention, as viewed from above.

### DETAILED DESCRIPTION OF PREFERRED EMBODIMENTS

Embodiments of the present invention are explained below with reference to the accompanying drawings.

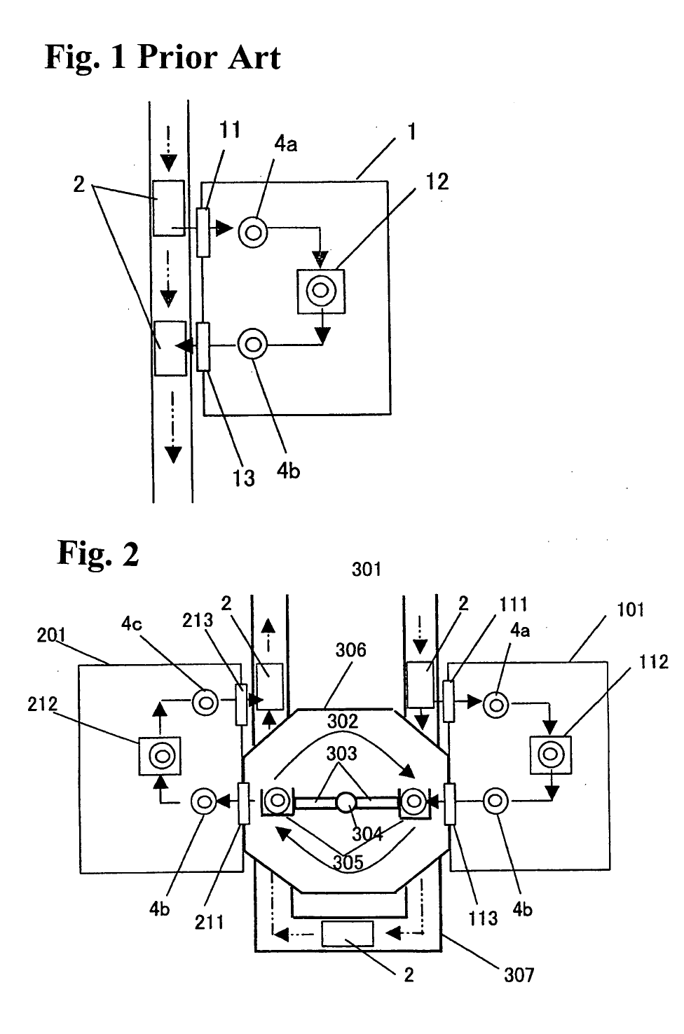

FIG. 1 is a schematic diagram of film formation on a magnetic recording medium using one conventional vacuum film-formation device. After completion of pre-processing such as cleaning, a plurality of substrate disks for magnetic recording media is loaded into a disk storing package 2, and is transported to a vacuum film-formation device 1. At an entrance 11 of the vacuum film-formation device 1, substrate disks 4a for magnetic recording media are unloaded, one by one, from the disk storing package 2, and are transported into a vacuum chamber 12 in the vacuum film-formation device. A thin film is then formed on the substrate by means of a sputtering device (not shown) inside the vacuum chamber 12.

The figure depicts only one vacuum chamber, though ordinarily a plurality of vacuum chambers is used. Once forming a film thereon, the substrates are transported to the next vacuum chamber, where further film formation is carried out to yield a multilayer thin film. A disk 4b having a film formed thereon is stored again in the disk storing package 2, at an exit 13 of the vacuum film-formation device. The disks after film formation are stored as a group, and are transported then to a subsequent process such as inspection.

FIG. 2 is a schematic diagram illustrating two vacuum film-formation devices connected via a connecting device of the present invention. The two connected vacuum film-formation devices may be of identical or dissimilar construction. FIG. 2 illustrates a vacuum film-formation device 101 and a vacuum film-formation device 201 connected to each other by way of a connecting device 301. After completion of pre-processing such as cleaning, a plurality of substrate disks for magnetic recording media is loaded into a disk storing package 2, and is transported to a vacuum film-formation device 101.

At an entrance 111 of the vacuum film-formation device 101, substrate disks 4a for magnetic recording media are unloaded, one by one, from the disk storing package 2, and are transported into a vacuum chamber 112 in the vacuum film-formation device. A thin film is then formed on the substrate by means of a sputtering device (not shown) inside the vacuum chamber 112. The figure depicts only one vacuum chamber, though ordinarily a plurality of vacuum chambers is used. Once a film is formed thereon, the substrate is transported to the next vacuum chamber, where further film formation is carried out to yield multilayer thin films. The process thus far is identical to the conventional film formation of a magnetic recording medium using one vacuum film-formation device, as explained in FIG. 1.

A disk 4b having a film formed thereon is unloaded at an exit 113 of the vacuum film-formation device 101, and is transported, disk by disk, to an entrance 211 of the vacuum film-formation device 201 by way of the connecting device 301 that is equipped with a disk transport system 302. The disk transport system 302 enables faster transport, in no more than 30 seconds, than transport by means of the disk storing package. The disk transport system 302 constitutes thus an efficient structure.

As in the vacuum film-formation device 101, film formation is carried out in a vacuum chamber 212 in the vacuum film-formation device 201. A disk 4c having a further film formed thereon is stored again in the disk storing package 2, at an exit 213 of the vacuum film-formation device. The disks after film formation are stored as a group thereof, and are transported then to a subsequent process such as inspection.

More preferably, the connecting device comprises a disk transport system 302 disposed in a vacuum chamber 306. Film formation can be carried out during the film formation process, without ever breaking the vacuum, by arranging the disk transport system 302 in the vacuum chamber 306. More preferably, the disk transport system comprises a motor 304 provided in the center of an arm 303, and a disk holding mechanism 305 provided at both ends of the arm 303. At the exit 113 of the vacuum film-formation device 101, the disk 4b having a film formed thereon is unloaded and is held by the disk holding mechanism 305. The motor 304 rotates the arm 303 by substantially 180°, to transport thereby the held disk 4b up to the entrance 211 of the vacuum film-formation device 201. Preferably, the disk 4b is held substantially vertically at the tip of the arm 303. The orientation of the disk surface is preferably maintained during transport through rotation of the arm 303. The disk holding mechanism 305 is provided at both ends of the arm 303, and hence a subsequent disk can be held straightway, which makes for efficient disk transport.

It may be also convenient to provide concomitantly, in addition to the disk transport system 302, a system 307 that enables transport by the disk storing package 2, such that film formation can also take place in case of malfunction of the disk transport system 302.

The present invention can be used in the manufacture of various magnetic recording media.

The disclosure of Japanese Patent Application No. 2008-017476 filed on Jan. 29, 2008 is incorporated as a reference.

While the invention has been explained with reference to the specific embodiments of the invention, the explanation is illustrative and the invention is limited only by the appended claims.

What is claimed is:

1. A method for manufacturing a magnetic recording medium, comprising the step of:
preparing a plurality of vacuum film-formation devices formed separately and operated independently, and
connecting the plurality of vacuum film-formation devices by a connecting device provided with a disk transport system.

2. The method for manufacturing a magnetic recording medium according to claim 1, wherein the connecting device is provided with a disk transport system in a vacuum state.

3. The method for manufacturing a magnetic recording medium according to claim 1, wherein transport time between the connected vacuum film-formation devices is no greater than 60 seconds.

4. The method for manufacturing a magnetic recording medium according to claim 3, wherein the transport time between the connected vacuum film-formation devices is no greater than 30 seconds.

5. The method for manufacturing a magnetic recording medium according to claim 1, wherein a magnetic recording medium on which a plurality of films is deposited thereon in one vacuum film-formation device is transferred to an exit of the one vacuum film-formation device, is held by an arm of a connecting device, and is transferred to an entrance of another vacuum film-formation device by rotation of the arm of the connecting device.

6. A connecting device for connecting vacuum film-formation devices used for manufacturing a magnetic recording medium, the connecting device comprising a disk transport system.

7. The connecting device according to claim 6, further comprising a system for generating a vacuum state in the connecting device.

8. The connecting device according to claim 6, wherein the disk transport system includes an arm for holding a disk at a tip thereof, and a device for rotating the arm to transport the disk through rotation of the arm.

9. The connecting device according to claim 8, wherein the disk is held substantially vertically at the tip of the arm.

10. The connecting device according to claim 9, wherein the arm is arranged such that orientation of a disk surface is maintained during transport through rotation of the arm.

11. The connecting device according to claim 6, further comprising a system for transporting the disks with a disk storing package.
